(19) United States
(12) Patent Application Publication
(10) Pub. No.: US 2025/0089363 A1
(43) Pub. Date: Mar. 13, 2025

(54) SEMICONDUCTOR DEVICES

(71) Applicant: Wuhan China Star Optoelectronics Technology Co., Ltd., Wuhan, Hubei (CN)

(72) Inventors: Zhifu LI, Wuhan, Hubei (CN); Guanghui LIU, Wuhan, Hubei (CN); Fei AI, Wuhan, Hubei (CN); Chengzhi LUO, Wuhan, Hubei (CN)

(73) Assignee: Wuhan China Star Optoelectronics Technology Co., Ltd., Wuhan, Hubei (CN)

(21) Appl. No.: 18/289,033

(22) PCT Filed: Jun. 29, 2023
(86) PCT No.: PCT/CN2023/103789

§ 371 Date: Oct. 31, 2023

(30) Foreign Application Priority Data
Aug. 30, 2022 (CN) 202211059125.2

(51) Int. Cl. H01L 27/12; H01L 29/66; H01L 29/786

(52) U.S. Cl. CPC H10D 86/60; H10D 30/0321; H10D 30/6713; H10D 30/6728; H10D 30/6746; H10D 30/6757; H10D 86/0221; H10D 86/421

(57) ABSTRACT

The present disclosure provides semiconductor devices. A first active layer is disposed on a substrate. A first insulation layer covers the first active layer and is provided with a first via hole. A second active layer is disposed on the first insulation layer. A third active layer is disposed in the first via hole and connects the first active layer and the second active layer, so that a channel length of the semiconductor device is determined by a thickness of the first insulation layer, and a channel width of the semiconductor device is determined by a circumference of the first via hole.

### TECHNICAL FIELD

The present disclosure relates to the field of display technologies, and in particular, to semiconductor devices.

### BACKGROUND

In order to meet the increasing requirements in parameters such as narrow border, high aperture ratio, and high resolution, an area occupied by semiconductor devices needs to be adjusted to be as small as possible. However, an active layer of the existing semiconductor device is flatly arranged as illustrated in FIG. 1, which causes the semiconductor device to occupy a large area. At the same time, as limited by exposure accuracy and etching accuracy, a channel length of the semiconductor device is more than 1 micron, which is not conducive to improve the mobility of the semiconductor device.

### SUMMARY OF THE INVENTION

Embodiments of the present disclosure provide semiconductor devices, which may reduce an occupied area and the mobility thereof.

Embodiments of the present disclosure provide a semiconductor device, including a substrate, a first active layer, a first insulation layer, and a second active layer. The first active layer is disposed on the substrate, the first insulation layer covers the first active layer, and the second active layer is disposed on the first insulation layer. The first insulation layer is provided with a first via hole, and the third active layer is disposed in the first via hole and connects the first active layer and the second active layer.

Optionally, in some embodiments of the present disclosure, the semiconductor device further includes a first conductive layer, disposed in the first insulation layer, the first conductive layer includes a gate provided with a first opening. In a top view, the first via hole is disposed in the first opening.

Optionally, in some embodiments of the present disclosure, the third active layer includes a main body part and an extension part. The main body part is disposed in the first via hole, and the extension part is connected to the main body part and disposed between the second active layer and the first insulation layer. In the top view, an orthographic projection of a boundary of the main body part on the extension part is located within a boundary of the extension part.

Optionally, in some embodiments of the present disclosure, in the top view, the extension part partially overlaps the gate.

Optionally, in some embodiments of the present disclosure, a distance between the boundary of the extension part and the boundary of the main body part is greater than or equal to 0.5 microns and is less than or equal to 5 microns.

Optionally, in some embodiments of the present disclosure, the first via hole includes a first sub-hole and a second sub-hole communicated with each other in a thickness direction of the semiconductor device, a size of the second sub-hole is greater than a size of the first sub-hole, the main body part is disposed in the first sub-hole, and the extension part is disposed in the second sub-hole.

Optionally, in some embodiments of the present disclosure, the first insulation layer includes a first insulation sub-layer and a second insulation sub-layer. The first insulation sub-layer covers the first active layer, and the second insulation sub-layer covers the first conductive layer. The second active layer is disposed on the second insulation sub-layer.

Optionally, in some embodiments of the present disclosure, a film thickness of the first conductive layer is greater than or equal to 0.05 microns and is less than or equal to 1 micron, a thickness of the first insulation sub-layer is greater than or equal to 0.05 microns and is less than or equal to 0.5 microns, and a thickness of the second insulation sub-layer is greater than or equal to 0.05 microns and is less than or equal to 0.5 microns.

Optionally, in some embodiments of the present disclosure, the semiconductor device further includes a second conductive layer and a second insulation layer. The second conductive layer is disposed between the substrate and the first active layer. The second conductive layer includes a first electrode, covers the second conductive layer, and is provided with a second via hole. The first active layer is electrically connected to the first electrode through the second via hole.

Optionally, in some embodiments of the present disclosure, the semiconductor device further includes a third insulation layer and a third conductive layer. The third insulation layer covers the second active layer and is provided with a third via hole. The third conductive layer is disposed on the third insulation layer and includes a second electrode and an electrode connecting part spaced apart from the second electrode. The second electrode is electrically connected to the second active layer through the third via hole, and the electrode connecting part is electrically connected to the first electrode through a fourth via hole that penetrates through the third insulation layer, the first insulation layer, and the second insulation layer.

Optionally, in some embodiments of the present disclosure, the first electrode includes a first electrode part, a second electrode part, and a third electrode part connected between the first electrode part and the second electrode part. In a top view, the first electrode part partially overlaps the first active layer, and the second electrode part partially overlaps the electrode connecting part.

Optionally, in some embodiments of the present disclosure, a width of the third electrode part is less than a width of the second electrode part, and the width of the second electrode part is less than a width of the first electrode part.

Optionally, in some embodiments of the present disclosure, the first via hole has a shape of a circular truncated cone.

Optionally, in some embodiments of the present disclosure, the present disclosure also provides array substrates, and the array substrate includes any one of the above-mentioned semiconductor devices.

Optionally, in some embodiments of the present disclosure, the present disclosure also provides driver chips, and the driver chip includes any one of the above-mentioned semiconductor devices.

Optionally, in some embodiments of the present disclosure, the present disclosure also provides display panels, and the display panel includes any one of the above-mentioned semiconductor devices.

Optionally, in some embodiments of the present disclosure, the present disclosure also provides display devices, and the display device includes any one of the above-mentioned semiconductor devices.

### BENEFICIAL EFFECTS

Compared with the related art, the present disclosure provides a semiconductor device. The first active layer is disposed on the substrate, the first insulation layer covers the first active layer and is provided with a first via hole, the second active layer is located on the first insulation layer, and the third active layer is located in the first via hole and connects the first active layer and the second active layer, so that a channel length of the semiconductor device can be determined by the thickness of the first insulation layer, and a channel width of the semiconductor device can be determined by a circumference of the first via hole, which is beneficial to the manufacturing of the semiconductor device with extremely shorter channel length, and thus is also beneficial to improving the mobility of the semiconductor device. In addition, since the third active layer is located in the first via hole and connects the first active layer and the second active layer, compared with a design in which the first active layer, the second active layer, and the third active layer are all located in the same plane, the present disclosure may reduce the occupied area of the semiconductor device and avoid the limitations of exposure accuracy and etching accuracy.

### DESCRIPTION OF DRAWINGS

FIG. 1 is a schematic structural view of a semiconductor device in related art.

FIGS. 2A to 2D are schematic structural views of a semiconductor device provided by embodiments of the present disclosure.

FIG. 3 is a manufacturing flow chart of a semiconductor device provided by embodiments of the present disclosure.

FIGS. 4A to 4I are schematic structural views during the manufacturing of a semiconductor device provided by embodiments of the present disclosure.

FIGS. 5A to 5B are schematic structural views of a display panel provided by embodiments of the present disclosure.

### EMBODIMENTS OF THE INVENTION

In order to make the purposes, technical solutions, and effects of the present disclosure clearer, the present disclosure will be further described in detail below with reference to the accompanying drawings and examples. It should be understood that specific embodiments described here are only used to explain the present disclosure and are not intended to limit the present disclosure.

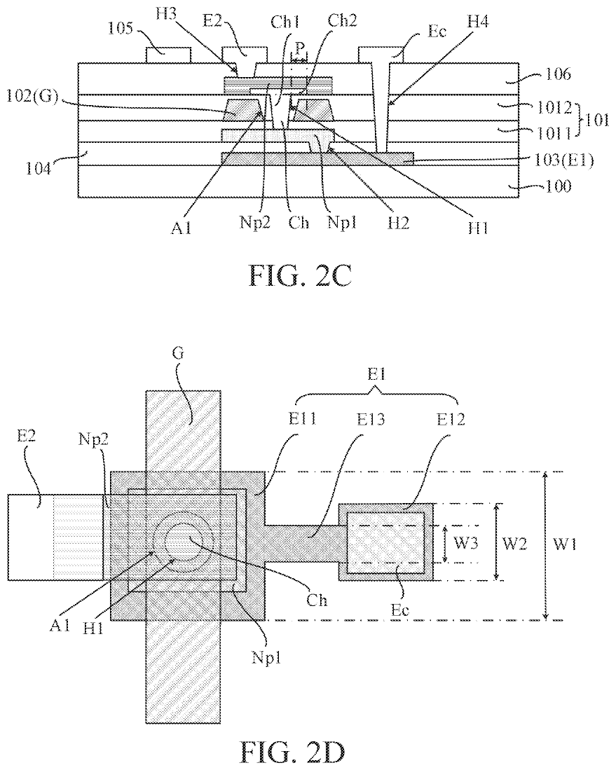

Specifically, FIG. 2A to FIG. 2D are schematic structural views of a semiconductor device provided by embodiments of the present disclosure. Embodiments of the present disclosure provide a semiconductor device, including a substrate 100, a first insulation layer 101, a first active layer Np1, a second active layer Np2, and a third active layer Ch.

Optionally, the substrate 100 is a flexible substrate or a rigid substrate. Optionally, a material of the substrate 100 is glass, polyimide, or the like.

The first active layer Np1 is located on the substrate 100.

The first insulation layer 101 covers the first active layer Np1, and the first insulation layer 101 is provided with a first via hole H1. Optionally, a material of the first insulation layer 101 includes silicon compound, metal oxide, and the like. Optionally, the material of the first insulation layer 101 is selected from silicon oxide, silicon nitride, silicon oxynitride, aluminum oxide, tantalum oxide, hafnium oxide, zirconium oxide, titanium oxide, etc. Optionally, the first insulation layer 101 may be a single-layer film structure, or may be a multilayer laminated structure with any combination of silicon oxide, silicon nitride, silicon oxynitride, aluminum oxide, tantalum oxide, hafnium oxide, zirconium oxide, titanium oxide, and the like.

The second active layer Np2 is located on the first insulation layer 101.

The third active layer Ch is located in the first via hole H1, and the third active layer Ch connects the first active layer Np1 and the second active layer Np2, so that a channel length of the semiconductor device is determined by a thickness of the first insulation layer 101 and a channel width of the semiconductor device is equal to a circumference of the first via hole H1, which is beneficial for realizing an extremely short channel length of the semiconductor device and improving the mobility of semiconductor device.

Optionally, the first active layer Np1 and the second active layer Np2 at least partially overlap, the third active layer Ch is located in the first via hole H1, and the third active layer Ch is correspondingly located between overlapping portions of the first active layer Np1 and the second active layer Np2. The first via hole H1 is completely filled by the third active layer Ch, so that the channel length of the semiconductor device is short.

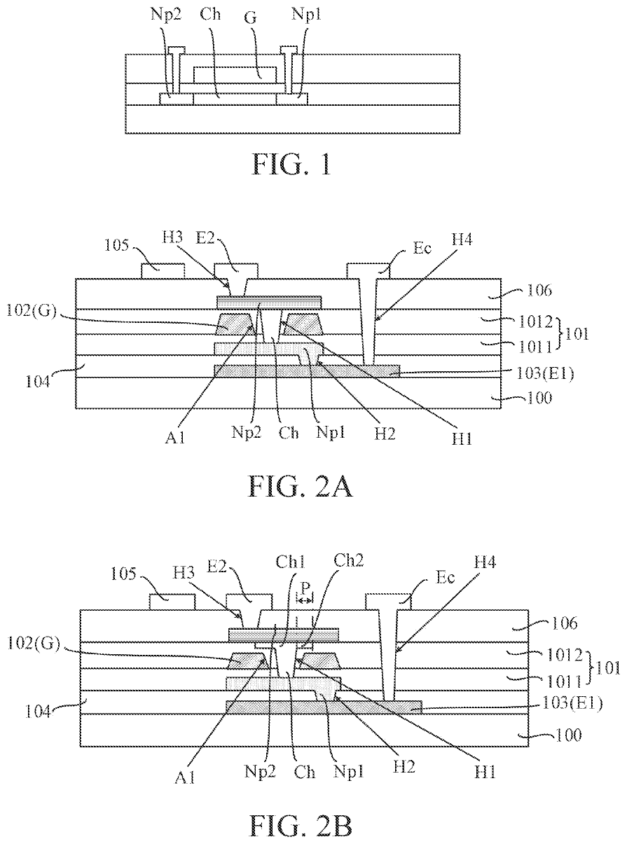

Since in the related art, the first active layer, the second active layer, and the third active layer are all located in the same horizontal plane (that is, as illustrated in FIG. 1), the channel length of the semiconductor device is determined by width of a gate G of the semiconductor device. Therefore, when manufacturing the semiconductor device, the exposure accuracy and the etching accuracy impose limitations on the channel length of the semiconductor device. In the present disclosure, since the third active layer Ch is located in the first via hole H1, so that the channel length of the semiconductor device is determined by the thickness of the first insulation layer 101, and the channel length of the semiconductor device is not limited by the exposure accuracy and the etching accuracy. The channel length of the semiconductor device ranges from 0.1 micron to 1 micron, which is significantly less than the channel length greater than 1 micron in the existing technology. That is, the channel length of the semiconductor device may be shorten to 0.1 micron, 0.2 micron, 0.3 micron, 0.4 micron, 0.5 micron, 0.6 micron, 0.7 micron, 0.8 micron, 0.9 micron, or 1 micron.

In addition, compared with the design in the related art in which the first active layer, the second active layer, and the third active layer are all located in the same horizontal plane, since the third active layer Ch in the present disclosure is located in the first opening H1 and connects the first active layer Np1 and the second active layer Np2, so that the first active layer Np1, the second active layer Np2, and the third active layer Ch at least partially overlap in a top view, and thus the occupied area of the semiconductor device may be reduced. In addition, in a thickness direction of the semiconductor device, since the first active layer Np1, the second active layer Np2, and the third active layer Ch are respectively located between different film layers, so that mutual interference between the first active layer Np1, the second active layer Np2, and the third active layer Ch may be reduced during the manufacturing of the semiconductor device.

It can be understood that when a top surface of the third active layer Ch is flush with a top surface of the first insulation layer 101, the channel length of the semiconductor device is less than or equal to the thickness of the first insulation layer 101, that is, the channel length of the semiconductor device is equal to a depth of the first via hole H1.

Optionally, the first via hole H1 has a shape of a circular truncated cone or a circular truncated cone with a step. Optionally, a width of the first via hole H1 gradually increases in a direction from the first active layer Np1 to the second active layer Np2, which reduces the difficulty of the manufacturing processes. It can be understood that the first via hole H1 may also be in a prism shape.

Continuing to refer to FIGS. 2A to 2C. The semiconductor device further includes a first conductive layer 102 located in the first insulation layer 101. The first conductive layer 102 includes a gate G of the semiconductor device, and the gate G is provided with a first opening A1. In the top view, the first via hole H1 is located in the first opening A1, so that the gate G is disposed corresponding to the third active layer Ch. The first conductive layer 102 is insulated from the first active layer Np1, the second active layer Np2, and the third active layer Ch through the first insulation layer 101.

Optionally, a material of the first conductive layer 102 includes at least one of molybdenum (Mo), aluminum (Al), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W), copper (Cu), tungsten (W), etc. Optionally, the first conductive layer 102 may be a single-layer film structure, or may be a laminated structure of Ti/Al/Ti, Mo/Al/Mo, Mo/AlGe/Mo, Cu/Mo, Cu/Ti, Cu/MoTi, Cu/MoNb, or the like.

Optionally, a shape of the first opening A1 may be a truncated cone, a prism, or the like. Optionally, a size of the first opening A1 is greater than or equal to 0.5 microns and is less than or equal to 15 microns. Optionally, the size of the first opening A1 is greater than or equal to 1 micron and is less than or equal to 10 microns. Optionally, the size of the first opening A1 may be equal to 0.5 microns, 0.6 microns, 0.7 microns, 0.8 microns, 0.9 microns, 1 microns, 5 microns, 10 microns, 11 microns, 12 microns, 13 microns, 14 microns, or 15 microns.

Optionally, continuing to refer to FIG. 2B, the third active layer Ch includes a main body part Ch1 and an extension part Ch2. The main body part Ch1 is located in the first via hole H1. The extension part Ch2 is connected to the main body part Ch1 and is located between the second active layer Np2 and the first insulation layer 101 to increase a contact effect between the third active layer Ch and the second active layer Np2. And/or, the extension part Ch2 is connected to the main body part Ch1 and is located between the first active layer Np1 and the first insulation layer 101 to increase a contact effect between the third active layer Ch and the first active layer Np1. In the top view, an orthographic projection of a boundary of the main body part Ch1 on the extension part Ch2 is located within a boundary of the extension part Ch2.

Optionally, in the top view, the extension part Ch2 partially overlaps the gate G, so as to increase a control area of the gate G and the third active layer Ch, which is beneficial for improving the control ability of the gate. It can be understood that, in order to avoid a short circuit between the extension part Ch2 and the gate G, the extension part Ch2 and the gate G overlap with the first insulation layer 101 interposed therebetween.

Optionally, a distance P between the boundary of the extension part Ch2 and the boundary of the main body part Ch1 is greater than or equal to 0.5 microns and is less than or equal to 5 microns, so as to increase the contact effect between the third active layer Ch and the second active layers Np2 and/or the first active layer Np1. Optionally, the distance P between the boundary of the extension part Ch2 and the boundary of the main body part Ch1 may be equal to 0.5 microns, 1 micron, 1.5 microns, 2 microns, 2.5 microns, 3 microns, 3.5 microns, 4 microns, 4.5 microns, or 5 microns. Optionally, the distance P between the boundary of the extension part Ch2 and the boundary of the main body part Ch1 is greater than or equal to 1 micron and is less than or equal to 3 microns.

Optionally, a distance between the main body part Ch1 and the gate G is greater than or equal to 0.05 micrometers and is less than or equal to 2 micrometers. Optionally, the distance between the main body part Ch1 and the gate G may be equal to 0.05 micron, 0.06 micron, 0.07 micron, 0.08 micron, 0.09 micron, 0.1 micron, 0.15 micron, 0.2 micron, 0.5 micron, 1 micron, 1.2 micron., 1.5 micron, 1.8 micron, or 2 micron.

Optionally, the extension part Ch2 may be located in the first via hole H1. That is, the first via hole H1 includes a first sub-hole and a second sub-hole that are communicated with each other in the thickness direction of the semiconductor device. A size of the second sub-hole is greater than a size of the first sub-hole, the main body part Ch1 is located in the first sub-hole, and the extension part Ch2 is located in the second sub-hole. In addition, the extension part Ch2 may also be located on the first insulation layer 101, which is as illustrated in FIG. 2C, so that the extension part Ch2 is located between the main body part Ch1 and the second active layer Np1; and/or, the extension part Ch2 may also be located under the first insulation layer 101, so that the extension part Ch2 is located between the main body part Ch1 and the first active layer Np1.

Optionally, to ensure that there is no short circuit between the first active layer Np1, the second active layer Np2, and the gate G, the first insulation layer 101 includes a first insulation sub-layer 1011 and a second insulation sub-layer 1012. The first insulation sub-layer 1011 covers the first active layer Np1, the second insulation sub-layer 1012 covers the first conductive layer 102, the second active layer Np2 is located on the second insulation sub-layer 1012, and the first via hole H1 penetrates the first insulation sub-layer 1011 and the second insulation sub-layer 1012.

It can be understood that the thicker the thicknesses of the first conductive layer 102 and the first insulation layer 101, the longer the channel length of the semiconductor device. In order to reduce the channel length of the semiconductor device, a film thickness of the conductive layer 102 is greater than or equal to 0.05 microns and is less than or equal to 1 micron, a thickness of the first insulation sub-layer 1011 is greater than or equal to 0.05 microns and is less than or equal to 0.5 microns, and a thickness of the second insulation sub-layer 1012 is greater than or equal to 0.05 microns and is less than or equal to 0.5 microns.

Optionally, the film thickness of the first conductive layer 102 may be equal to 0.05 microns, 0.08 microns, 0.1 microns, 0.15 microns, 0.2 microns, 0.25 microns, 0.3 microns, 0.4 microns, 0.45 microns, 0.5 microns, 0.55 microns, 0.6 micron, 0.65 micron, 0.7 micron, 0.8 micron, 0.9 micron, 0.95 micron, or 1 micron.

Optionally, the thickness of the first insulation sub-layer 1011 may be equal to 0.05 microns, 0.06 microns, 0.08 microns, 0.1 microns, 0.15 microns, 0.2 microns, 0.25 microns, 0.3 microns, 0.4 microns, 0.45 microns, 0.48 microns, or 0.5 microns.

Optionally, the thickness of the second insulation sub-layer 1012 may be equal to 0.05 microns, 0.06 microns, 0.08 microns, 0.1 microns, 0.15 microns, 0.2 microns, 0.25 microns, 0.3 microns, 0.4 microns, 0.45 microns, 0.48 microns, or 0.5 microns.

Optionally, the semiconductor device may be a field effect semiconductor device, a thin film semiconductor device, or the like.

When the semiconductor device is subsequently applied, both the first active layer Np1 and the second active layer Np2 need to be connected to corresponding signal lines or devices (for example, the first active layer Np1 may be electrically connected to a pixel electrode or a light-emitting device, and the second active layer Np2 may be electrically connected to signal lines such as data lines, etc.). Since the first active layer Np1 and the second active layer Np2 are located on different planes, so that a depth of the via hole exposing the first active layer Np1 and a depth of the via hole exposing the second active layer Np2 are different. When manufacturing the semiconductor device, over-etching of the first active layer Np1 or the second active layer Np2 may occur, which affects the performance of the semiconductor device. Thus, the semiconductor device may further include a second conductive layer 103, a second insulation layer 104, a third conductive layer 105, and a third insulation layer 106, as illustrated in FIGS. 2A to 2C.

The second conductive layer 103 is located between the substrate 100 and the first active layer Np1. The second conductive layer 103 includes a first electrode E1 electrically connected to the first active layer Np1.

The second insulation layer 104 covers the second conductive layer 103 and is provided with a second via hole H2 thereon. The first active layer Np1 is electrically connected to the first electrode E1 through the second via hole H2 which penetrates the second insulation layer 104.

The third insulation layer 106 covers the second active layer Np2 and is provided with a third via H3 thereon.

The third conductive layer 105 is located on the third insulation layer 106. The third conductive layer 105 includes a second electrode E2 and an electrode connecting part Ec. The second electrode E2 is electrically connected to the second active layer Np2. The electrode connecting part Ec is spaced apart from the second electrode E2 and is electrically connected to the first electrode E1. The second electrode E2 is electrically connected to the second active layer Np2 through a third via hole H3 which penetrates the third insulation layer 106. The electrode connecting part Ec is electrically connected to the first electrode E1 through a fourth via hole H4 which penetrates through the third insulation layer 106, the first insulation layer 101, and the second insulation layer 104.

Optionally, for the first electrode E1 and the second electrode E2, one is a source of the semiconductor device, and the one other one is a drain of the semiconductor device.

Optionally, the materials of the second conductive layer 103 and the third conductive layer 105 include at least one of molybdenum (Mo), aluminum (Al), platinum (Pt), palladium (Pd), silver (Ag), magnesium (Mg), Gold (Au), nickel (Ni), neodymium (Nd), iridium (Ir), chromium (Cr), calcium (Ca), titanium (Ti), tantalum (Ta), tungsten (W), copper (Cu), tungsten (W), and the like. Optionally, the second conductive layer 103 and the third conductive layer 105 may each be a single-layer film structure, or may each be a multilayer laminated structure of Ti/Al/Ti, Mo/Al/Mo, Mo/AlGe/Mo, Cu/Mo, Cu/Ti, Cu/MoTi, Cu/MoNb, or the like.

Optionally, materials of the second insulation layer 104 and the third insulation layer 106 include silicon compounds, metal oxides, and the like. Optionally, the materials of the second insulation layer 104 and the third insulation layer 106 may be selected from silicon oxide, silicon nitride, silicon oxynitride, aluminum oxide, tantalum oxide, hafnium oxide, and zirconium oxide, titanium oxide, etc. Optionally, the second insulation layer 104 and the third insulation layer 106 may each be a single-layer film structure, or may each be a multilayer laminated structure with any combination of silicon oxide, silicon nitride, silicon oxynitride, aluminum oxide, tantalum oxide, hafnium oxide, zirconium oxide, titanium oxide, and the like.

By arranging the first electrode E1, the second electrode E2, and the electrode connecting part Ec, the impact of etching and other processes on the first active layer Np1 and the second active layer Np2 may be reduced when manufacturing the semiconductor device, which enables the semiconductor device to have better performance.

Optionally, continuing to refer to FIGS. 2A to 2D, the first electrode E1 includes a first electrode part E11, a second electrode part E12, and a third electrode part E13 connected between the first electrode part E11 and the second electrode part E12. In the top view, the first electrode part E11 at least partially overlaps the first active layer Np1, and the second electrode part E12 at least partially overlaps the electrode connecting part Ec, so that the first active layer Np1 and the electrode connecting part Ec are electrically connected through the first electrode E1.

Optionally, an orthographic projection of the first active layer Np1 on the first electrode part E11 is located within a boundary of the first electrode part E11, so that the first electrode part E11 is used for shielding light for the active layer.

Optionally, a width W3 of the third electrode part E13 is less than a width W2 of the second electrode part E12, and the width W2 of the second electrode part E12 is less than a width W1 of the first electrode part E11, so as to reduce an area of the first electrode E1, thereby reducing the amount of charge accumulated on the first electrode E1, which reduces the probability of generating static electricity.

It can be understood that the semiconductor device may be applied in an integrated circuit (such as applied in driving chips, etc.), and may also be applied in pixel driving circuits, gate driving circuits, backlight driving circuits, amplifier circuits, switching circuits, and the like. It can be understood that the semiconductor device may be applied in the field of display technology (such as applied in array substrates, display panels, display devices, backlight modules, etc.), and may be applied in in the field of monitoring technology (such as applied in monitoring equipment), the field of detection technology (such as applied in detection equipment, etc.), the automotive field, or other fields.

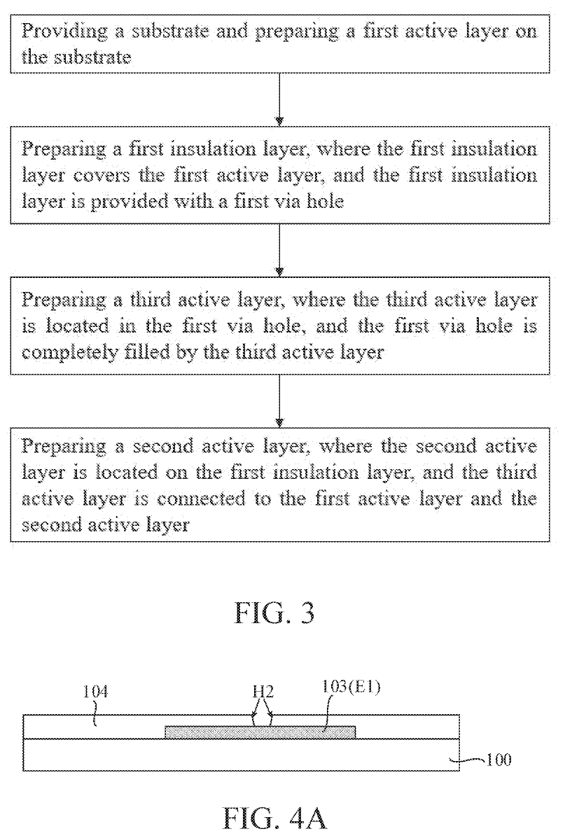

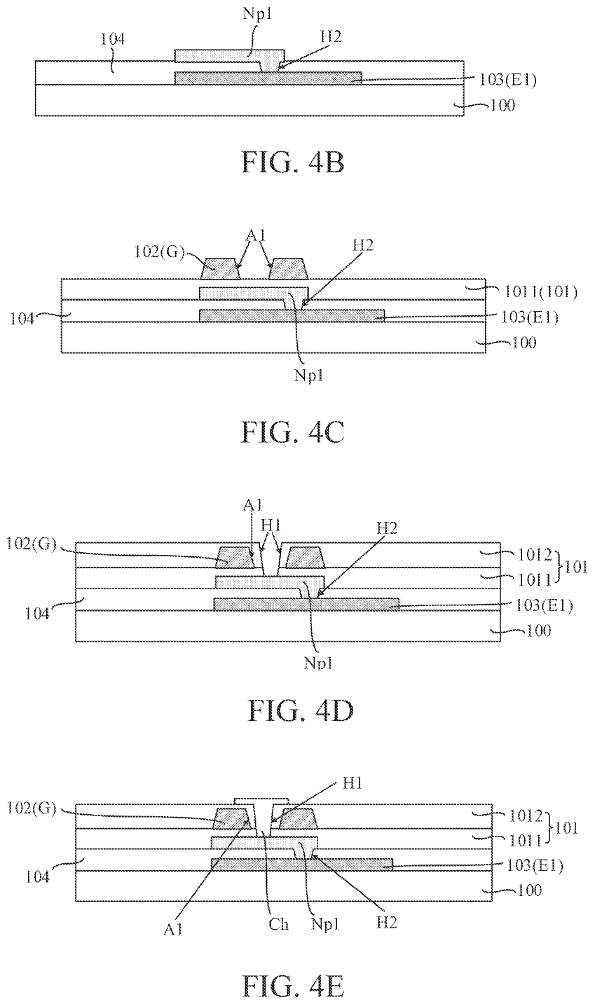

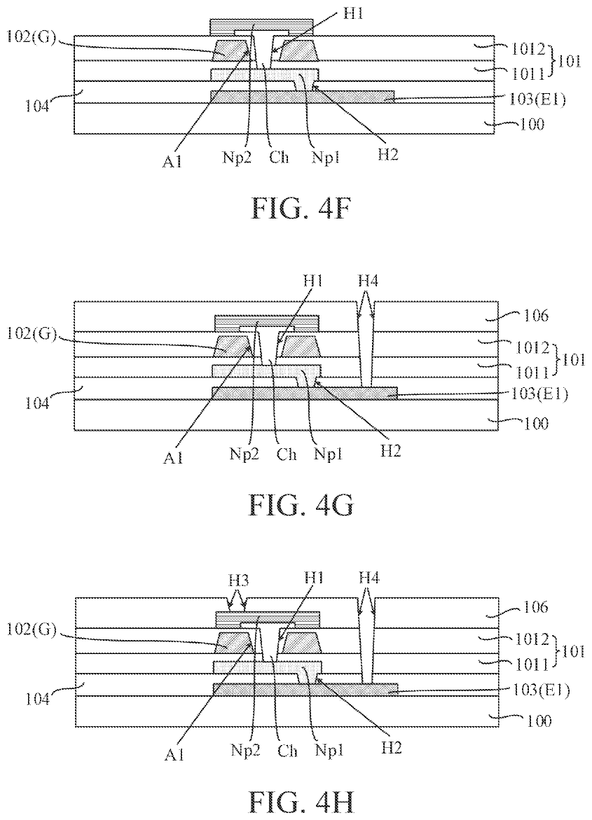

FIG. 3 is a manufacturing flow chart of the semiconductor device provided by embodiments of the present disclosure, and FIGS. 4A to 4I are schematic structural views during the manufacturing of the semiconductor device provided by embodiments of the present disclosure. The present disclosure also provides a manufacturing method of the semiconductor device, which is used to manufacture any one of the above-mentioned semiconductor devices. The manufacturing method of the semiconductor device includes:
a step S100 including: providing a substrate 100 and preparing a first active layer Np1 on the substrate 100, as illustrated in FIG. 4B;
a step S200 including: preparing a first insulation layer 101, where the first insulation layer 101 covers the first active layer Np1, and the first insulation layer 101 is provided with a first via hole H1, as illustrated in FIG. 4D;
a step S300 including: preparing a third active layer Ch, where the third active layer Ch is located in the first via hole H1, and the first via hole H1 is completely filled by the third active layer Ch, as illustrated in FIG. 4E; and
a step S400 including: preparing a second active layer Np2 as illustrated in FIG. 4F, where the second active layer Np2 is located on the first insulation layer 101, and the third active layer Ch is connected to the first active layer Np1 and the second active layer Np2.

Optionally, in the top view, the first active layer Np1 and the second active layer Np2 at least partially overlap, the third active layer Ch is connected between the first active layer Np1 and the second active layer Np2, and the third active layer Ch is correspondingly located between the overlapping portions of the first active layer Np1 and the second active layer Np2, so that the semiconductor device has a shorter channel length.

Optionally, the first active layer Np1 is prepared through processes of amorphous silicon film formation, excimer laser annealing, exposure, etching, and ion doping. The second active layer Np2 is prepared through processes of amorphous silicon film formation, excimer laser annealing, exposure, etching, and ion doping. The third active layer Ch is prepared through processes of amorphous silicon film formation, excimer laser annealing, exposure, and etching. The first insulation layer 101 is exposed and etched to form the first via hole H1.

Optionally, the step S200 also includes: preparing a first conductive layer 102 as illustrated in FIG. 4C, where the first conductive layer 102 is located in the first insulation layer 101, the first conductive layer 102 includes a gate G of the semiconductor device, and the gate G is provided with a first opening A1. In the top view, the first via hole H1 is located in the first opening A1.

Optionally, the first conductive layer 102 is prepared through processes of film formation, exposure, and etching to obtain the gate G provided with the first opening A1.

Optionally, the first insulation layer 101 includes a first insulation sub-layer 1011 and a second insulation sub-layer 1012. The step S200 further includes steps of S201, S202, and S203.

The step S201 includes: preparing the first insulation sub-layer 1011 on the first active layer Np1.

The step S202 includes: preparing the first conductive layer 102 on the first insulation sub-layer 1011, where the first conductive layer 102 includes the gate G provided with the first opening A1, as illustrated in FIG. 4C.

The step S203 includes: preparing the second insulation sub-layer 1012 on the first conductive layer 102, where the first via hole H1 penetrates the first insulation sub-layer 1011 and the second insulation sub-layer 1012 and exposes the first active layer Np1, as illustrated in FIG. 4D.

Optionally, the step S100 also includes: preparing a second conductive layer 103 on the substrate 100, where the second conductive layer 103 includes a first electrode E1 electrically connected to the first active layer Np1. Optionally, the second conductive layer 103 is subjected by processes of film formation, exposure, and etching to obtain the first electrode E1.

Optionally, the step $100 also includes: preparing a second insulation layer 104 on the second conductive layer 103, and forming a second via H2 which penetrates the second insulation layer 104 and exposes the first electrode E1, as illustrated in FIG. 4A, where the first active layer Np1 is electrically connected to the first electrode E1 through the second via hole H2. Optionally, the second insulation layer 104 is subjected by processes of film formation, exposure, and etching to form the second via hole H2.

Optionally, after the step S400, the manufacturing method also includes: preparing a third insulation layer 106 on the second active layer Np2, forming a fourth via hole H4 which penetrates through the third insulation layer 106, the second insulation sub-layer 1012, the first insulation sub-layer 1011, and the second insulation layer 104 and exposes the first electrode E1, and forming a third via hole H3 which penetrates the third insulation layer 106 and exposes the second active layer Np2, as illustrated in FIGS. 4G to 4H. Optionally, the third insulation layer 106 is subjected by processes of film formation, hydrogen activation, exposure, and etching to form the fourth via hole H4 and the third via hole H3. Optionally, the third via hole H3 and the fourth via hole H4 may also be formed through a half-tone mask.

Optionally, after step S400, the manufacturing method also includes: preparing a third conductive layer 105, where the third conductive layer 105 includes a second electrode E2 and an electrode connecting part Ec, the second electrode E2 is electrically connected to the second active layer Np2, and the electrode connecting part Ec is spaced apart from the second electrode E2 and is electrically connected to the first electrode E1. The second electrode E2 is electrically connected to the second active layer Np2 through the third via hole H3, and the electrode connecting part Ec is connected to the first electrode E1 through the fourth via hole H4, as illustrated in FIG. 4I. Optionally, the third conductive layer 105 is subjected by processes film formation, exposure, and etching to obtain the second electrode E2 and the electrical connection portion Ec.

It can be understood that the third active layer Ch may also adopt a structure illustrated in FIG. 2A and FIG. 2B.

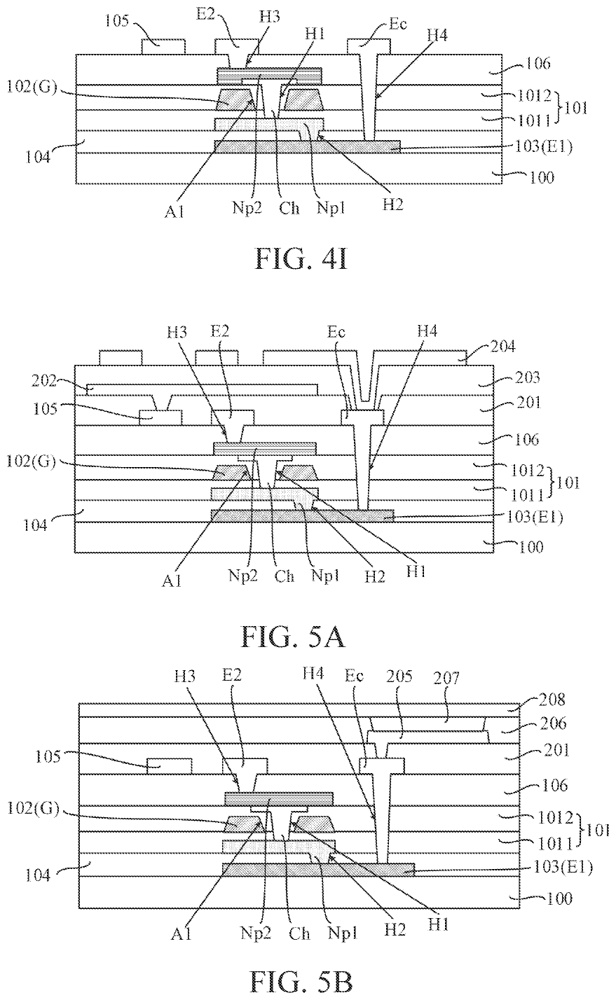

FIGS. 5A to 5B are schematic structural views of a display panel provided by embodiments of the present disclosure. The present disclosure also provides display panels, and the display panel includes any one of the above-mentioned semiconductor devices or a semiconductor device manufactured by to any one of the above-mentioned manufacturing methods.

Optionally, the display panel may be a passive luminescent display panel or a self-luminous display panel. Optionally, the display panel may be a liquid crystal display panel, a touch display panel, or a display panel including light-emitting devices. Optionally, the light- emitting devices may include organic light-emitting diodes, sub-millimeter light-emitting diodes, micro light-emitting diodes, etc.

Continuing to refer to FIG. 5A, the display panel further includes a planarization layer 201, a bottom electrode 202 disposed on the planarization layer, a protective layer 203 disposed on the bottom electrode 202, and a top electrode 204 disposed on the protective layer 203. Optionally, the third conductive layer 105 further includes a first connection portion, the bottom electrode is electrically connected to the first connection portion through a via hole penetrating the planarization layer 201, and the top electrode 204 is electrically connected to the electrode connecting part Ec through another via hole penetrating the planarization layer 201 and the protective layer 203.

Optionally, the bottom electrode 202 is a touch electrode, and the top electrode 204 is a pixel electrode. Optionally, the bottom electrode 202 and the top electrode 204 are transparent electrodes.

Continuing to refer to FIG. 5B, the display panel also includes the planarization layer 201, an anode layer 205, a pixel definition layer 206, a light-emitting layer 207 and a cathode layer 208. The anode layer 205 is located on the planarization layer 201 and includes a plurality of anodes electrically connected to the electrode connecting part Ec. The pixel definition layer 206 is located on the anode layer 205 and is provided with pixel definition areas exposing the anodes. The light-emitting layer 207 is disposed in the pixel definition areas. The cathode layer 208 is disposed on the light-emitting layer 207 and includes a plurality of cathodes. The light-emitting device includes the anode, the light-emitting layer, and the cathode. It can be understood that the third active layer Ch may also adopt a structure illustrated in FIG. 2A and FIG. 2B.

The present disclosure also provides display devices, and the display device includes any one of the above-mentioned semiconductor devices or a semiconductor device manufactured by any one of the above-mentioned manufacturing methods. It can be understood that the display device may be a movable display device (such as a laptop computer, a mobile phone, etc.), a fixed terminal (such as a desktop computer, a television, etc.), a measuring device (such as a sports bracelet, a thermometer, etc.), or the like.

This paper uses specific examples to illustrate the principles and implementation methods of the present disclosure. The description of the above embodiments is only used to help understand the methods and core idea of the present disclosure. At the same time, for those skilled in the art, there will be changes in the specific implementation and application scope based on the ideas of the present disclosure. In summary, the content of this description should not be understood as a limitation of the present disclosure.

1. A semiconductor device, comprising:
a substrate;
a first active layer, disposed on the substrate;
a first insulation layer, covering the first active layer; and
a second active layer, disposed on the first insulation layer,
wherein the first insulation layer is provided with a first via hole, and the third active layer is disposed in the first via hole and connects the first active layer and the second active layer.

2. The semiconductor device according to claim 1, further comprising:
a first conductive layer, disposed in the first insulation layer and comprising a gate provided with a first opening, wherein in a top view, the first via hole is disposed in the first opening.

3. The semiconductor device according to claim 2, wherein the third active layer comprises:
a main body part, disposed in the first via hole; and
an extension part, connected to the main body part and disposed between the second active layer and the first insulation layer,
wherein in the top view, an orthographic projection of a boundary of the main body part on the extension part is located within a boundary of the extension part.

4. The semiconductor device according to claim 3, wherein in the top view, the extension part partially overlaps the gate.

5. The semiconductor device according to claim 4, wherein a distance between the boundary of the extension part and the boundary of the main body part is greater than or equal to 0.5 microns and is less than or equal to 5 microns.

6. The semiconductor device according to claim 3, wherein the first via hole comprises a first sub-hole and a second sub-hole communicated with each other in a thickness direction of the semiconductor device, a size of the second sub-hole is greater than a size of the first sub-hole, the main body part is disposed in the first sub-hole, and the extension part is disposed in the second sub-hole.

7. The semiconductor device according to claim 2, wherein the first insulation layer comprises:
a first insulation sub-layer, covering the first active layer; and
a second insulation sub-layer, covering the first conductive layer,
wherein the second active layer is disposed on the second insulation sub-layer.

8. The semiconductor device according to claim 7, wherein a film thickness of the first conductive layer ranges between 0.05 microns and 1 micron, a thickness of the first insulation sub-layer ranges between 0.05 microns and 0.5 microns, and a thickness of the second insulation sub-layer ranges between 0.05 microns and 0.5 microns.

9. The semiconductor device according to claim 1, further comprising:
a second conductive layer, disposed between the substrate and the first active layer and comprising a first electrode; and
a second insulation layer, covering the second conductive layer and provided with a second via hole,
wherein the first active layer is electrically connected to the first electrode through the second via hole.

10. The semiconductor device according to claim 9, further comprising:
a third insulation layer, covering the second active layer and provided with a third via hole; and
a third conductive layer, disposed on the third insulation layer, and comprising:
a second electrode; and
an electrode connecting part, spaced apart from the second electrode,
wherein the second electrode is electrically connected to the second active layer through the third via hole, and the electrode connecting part is electrically connected to the first electrode through a fourth via hole that penetrates through the third insulation layer, the first insulation layer, and the second insulation layer.

11. The semiconductor device according to claim 10, wherein the first electrode comprises:
a first electrode part;
a second electrode part; and
a third electrode part, connected between the first electrode part and the second electrode part,
wherein in a top view, the first electrode part partially overlaps the first active layer, and the second electrode part partially overlaps the electrode connecting part.

12. The semiconductor device according to claim 11, wherein a width of the third electrode part is less than a width of the second electrode part, and the width of the second electrode part is less than a width of the first electrode part.

13. The semiconductor device according to claim 1, wherein the first via hole has a shape of a circular truncated cone.
